(19) United States
(12) Patent Application Publication
(10) Pub. No.: US 2024/0224644 A1
(43) Pub. Date: Jul. 4, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ling SHI, Beijing (CN); Yipeng CHEN, Beijing (CN); Lang LIU, Beijing (CN); Dan GUO, Beijing (CN); Chuntong JIANG, Beijing (CN); Xuewei TIAN, Beijing (CN)

(21) Appl. No.: 18/292,310

(22) PCT Filed: Aug. 26, 2021
(86) PCT No.: PCT/CN2021/114789

§ 371 Date: Jan. 25, 2024

(51) Int. Cl. H10K 59/131; H10K 59/65

(52) U.S. Cl. CPC H10K 59/131; H10K 59/65

(57) ABSTRACT

A display panel and a display device. A display area of the display panel comprises a light-transmitting display area (b) and a non-light-transmitting display area (a), the density of pixel circuits of the light-transmitting display area (b) being lower than that of the non-light-transmitting display area (a). The portion of the display panel that is located at the light-transmitting display area (b) comprises: a base substrate; a plurality of pixel circuits (10), wherein the plurality of pixel circuits (10) are arranged on one side of the base substrate; and a signal line, which is used for connecting different pixel circuits (10), wherein the signal line comprises a transparent wire (20) and a metal wire (30), and the metal wire (30) is aperiodically arranged.

### CROSS-REFERENCE TO RELATED APPLICATION

The present application is a U.S. National Phase Entry of International Application No. PCT/CN2021/114789 having an international filing date of Aug. 26, 2021, the entire content of which is hereby incorporated by reference.

### TECHNICAL FIELD

The present disclosure relates to the field of display technologies, and specifically to a display panel and a display device.

### BACKGROUND

An Organic Light Emitting Diode (OLED) display panel has gradually become the mainstream in the display field due to its excellent performances such as low power consumption, high color saturation, a wide angle of view, thin thickness, and a capability for achieving flexibility, etc. The OLED display panel may be widely applied in smart phones, tablet computers, televisions, and other terminal products. At present, in order to increase a screen-to-body ratio of a display screen, a camera may be placed on a back side of a display panel, that is, an under-screen camera is obtained, so the display panel corresponding to the under-screen camera needs to have relatively high light transmittance, so as to meet a demand of the under-screen camera on a light input amount without affecting a normal display function of this region at the same time.

### SUMMARY

The present disclosure aims at solving one of technical problems in the related art at least to a certain extent. To this end, a purpose of the present disclosure is to provide a display panel, a light-transmitting display region of which has relatively good light transmittance and is not prone to an occurrence of a light diffraction phenomenon.

In an aspect of the present disclosure, the present disclosure provides a display panel. According to an embodiment of the present disclosure, a display region of the display panel includes a light-transmitting display region and a non-light-transmitting display region, a pixel circuit density of the light-transmitting display region being less than a pixel circuit density of the non-light-transmitting display region, and the display panel at the light-transmitting display region includes: a base substrate; multiple pixel circuits, disposed on a side of the base substrate; and signal lines, wherein the signal lines are configured to connect different pixel circuits, the signal lines include transparent traces and metal traces, and the metal traces are arranged in an aperiodic mode. Therefore, an occurrence of diffraction of light rays passing through the light-transmitting display region may be effectively improved.

According to an embodiment of the present disclosure, the metal traces are not completely disposed in a same layer.

According to an embodiment of the present disclosure, orthographic projections of the metal traces disposed in different layers on the base substrate are not completely overlapped.

According to an embodiment of the present disclosure, a metal trace is at least a part of at least one of a data signal line and a Gate signal line.

According to an embodiment of the present disclosure, a metal trace has a width of 1.5 microns to 2 microns.

According to an embodiment of the present disclosure, multiple pixel circuits are disposed in an array, defining pixel circuits of (2˜4)*(2˜4) as a pixel repeating unit, and pixel repeating units of 5 rows*5 columns as a pixel definition region, wherein at least part of the signal lines in each pixel definition region are the metal traces.

According to an embodiment of the present disclosure, at least part of the signal lines in each pixel repeating unit are the metal traces.

According to an embodiment of the present disclosure, in each pixel definition region, a distribution area of the metal traces is less than or equal to 2% of an area occupied by the pixel definition region.

According to an embodiment of the present disclosure, light transmittance of the light-transmitting display region is 11% to 15%.

In an aspect of the present disclosure, the present disclosure provides a display device. According to an embodiment of the present disclosure, the display device includes the display panel described above; and an under-screen camera, wherein an orthographic projection of the under-screen camera on the display panel has an overlapping region with the light-transmitting display region of the display panel. Therefore, it is not prone to an occurrence of diffraction of light rays passing through the light-transmitting display region of the display panel, and further a shooting quality of the under-screen camera may be effectively improved. It will be understood by those skilled in the art that the display device has all features and advantages of the display panel described above, which will not be repeated too much here.

### BRIEF DESCRIPTION OF DRAWINGS

FIG. 1 is a schematic diagram of a division of a display region of a display panel in an embodiment of the present disclosure.

FIG. 2 is a planar schematic diagram of a partial structure in a display panel in another embodiment of the present disclosure.

FIG. 3 is a planar schematic diagram of a partial structure in a display panel in another embodiment of the present disclosure.

FIG. 4 is a planar schematic diagram of a partial structure in a display panel in another embodiment of the present disclosure.

FIG. 5 is a planar schematic diagram of a partial structure in a display panel in yet another embodiment of the present disclosure.

FIG. 6 is a planar schematic diagram of a partial structure in a display panel in yet another embodiment of the present disclosure.

FIG. 7 is a schematic diagram of a structure of a display device in yet another embodiment of the present disclosure.

FIG. 8 is a schematic diagram of a distribution of pixel circuits in a display panel in an embodiment of the present disclosure.

### DETAILED DESCRIPTION

Embodiments of the present disclosure are described in detail below. Embodiments described below are exemplary and are only used for explaining the present disclosure, but should not be construed as limitations on the present disclosure. Those not indicated with specific technologies or conditions in the embodiments are performed according to technologies or conditions described in documents in the art or according to a product specification.

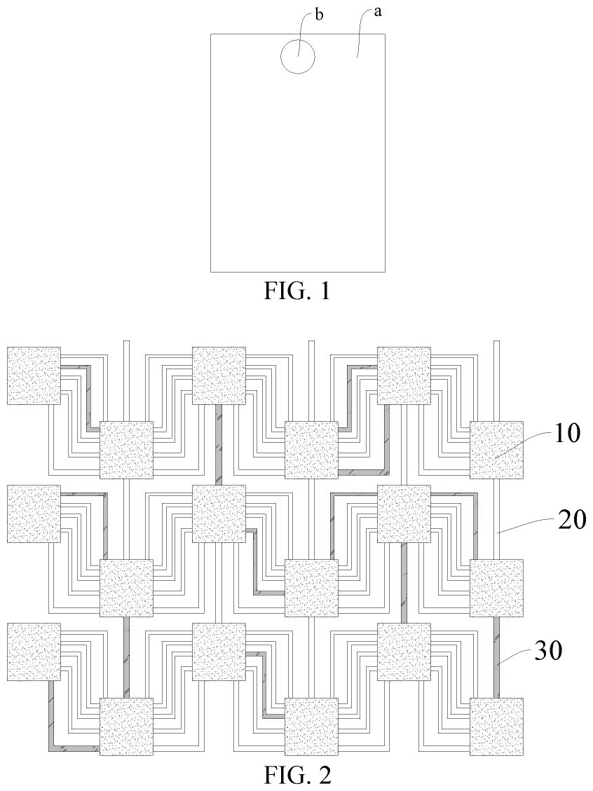

In an aspect of the present disclosure, the present disclosure provides a display panel. According to an embodiment of the present disclosure, a display region of the display panel includes a light-transmitting display region b and a non-light-transmitting display region a (as shown in FIG. 1), a pixel circuit density of the light-transmitting display region being less than a pixel circuit density of the non-light-transmitting display region. Referring to FIG. 2, the display panel at the light-transmitting display region includes: a base substrate (not shown in FIG. 2); multiple pixel circuits, disposed on a side of the base substrate; and signal lines, wherein the signal lines are configured to connect different pixel circuits 10, and the signal lines include transparent traces 20 and metal traces 30. Therefore, metal traces are usually opaque, so that a periodic arrangement of pixel circuits in the light-transmitting display region may be disturbed, and further an occurrence of diffraction of light rays passing through the light-transmitting display region may be effectively improved, improving a shooting quality of an under-screen camera.

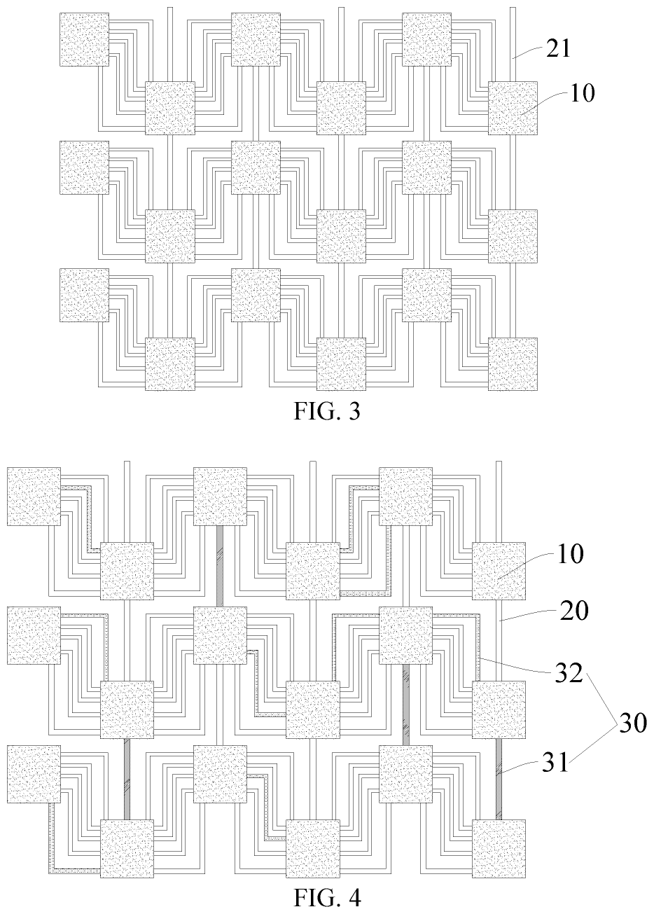

It should be noted that a pixel circuit described in this document refers to a driving circuit configured to provide a driving voltage for an OLED light emitting device, which may be in a circuit structure of 7T1C, 9T2C, 2T1C, or the like. It should be noted that the pixel circuit is configured to drive a light emitting device (OLED device) to emit light, and includes an active layer, a gate, a source-drain electrode, a storage capacitor, a data line, a scan line, and other structures. In order to ensure relatively high light transmittance of the light-transmitting display region, referring to FIG. 3, signal lines in the display panel at the light-transmitting display region may each be set as transparent traces 20. However, the inventor found that since the pixel circuits are all periodically arranged, signal lines configured to electrically connect the pixel circuits are also arranged in a periodic mode, other regions except the pixel circuits are light-transmitting regions, and signal lines in the regions are all transparent traces, so the above light-transmitting regions are also arranged in a periodic mode. The entire light-transmitting display region is as a whole similar to a grating, so an occurrence of diffraction of light rays when passing through the light-transmitting display region will be caused. If the back of the display panel at the light-transmitting display region is provided with an under-screen camera, the occurrence of the diffraction of the light rays will greatly affect a shooting quality of the under-screen camera. Through a series of studies, the inventor found that part of transparent traces therein may be set as metal traces, and the metal traces are usually opaque, so that the periodic arrangement of the pixel circuits may be disturbed, and further an occurrence of diffraction of transmitted light rays may be avoided, improving the shooting quality of the under-screen camera.

Herein, referring to FIG. 8, the pixel circuit density of the light-transmitting display region b is less than the pixel circuit density of the non-light-transmitting display region a, that is, a quantity of pixel circuits 10 of the light-transmitting display region b is less than a quantity of pixel circuits 10 of the non-light-transmitting display region a, so that light transmittance of the light-transmitting display region may be improved. Specific pixel circuit densities of the light-transmitting display region and the non-light-transmitting display region have no special demands, and technicians in the art can flexibly select the specific pixel circuit densities of the light-transmitting display region and the non-light-transmitting display region according to actual situations such as a specific demand on the display panel and a demand on the light transmittance of the light-transmitting display region, etc.

Herein, a specific disposed position of the light-transmitting display region b has no special demand, and technicians in the art can flexibly choose according to an actual design demand. For example, the light-transmitting display region b may be the center of the display panel, or may be a corner of the display panel, or may be located near a border and in the center of the display panel as shown in FIG. 1.

Moreover, a specific shape of the light-transmitting display region b has no special demand, and technicians in the art can flexibly choose according to an actual situation. For example, the shape of the light-transmitting display region b includes but is not limited to polygons such as circle, ellipse, quadrilateral, pentagonal, hexagonal, or the like, or an irregular pattern.

It should be noted that the above “signal lines” include signal lines correspondingly disposed in the display panel at the light-transmitting display region, including a reset control signal line (Rst), a scan signal line (Gate signal line), a light emitting control signal line (EM), a reset power supply signal line (Init), a power supply signal line VDD, a data signal line (data signal line), and other signal lines.

According to an embodiment of the present disclosure, as described above, the “signal lines” include signal lines correspondingly disposed in the display panel at the light-transmitting display region, including a reset control signal line (Rst), a scan signal line (Gate signal line), a light emitting control signal line (EM), a reset power supply signal line (Init), a power supply signal line VDD, a data signal line (data signal line), and other signal lines. Therefore, when a part of the signal lines disposed in different layers are selected to be set as metal traces, the metal traces are not completely disposed in a same layer. Therefore, technicians in the art can more flexibly select disposed positions of the metal traces according to a design requirement, and can provide more solutions to break a periodic arrangement of pixel units, that is, to break a periodic arrangement of light-transmitting regions with no pixel arranging, so as to improve a situation of diffraction of light.

Herein, when metal traces are disposed in different signal lines, there is no special restriction on specific disposing demands on the metal traces in the different signal lines, as long as the metal traces are not uniformly distributed. Further, when metal traces are disposed in different signal lines, the different signal lines may be different signal lines disposed in a same layer (e.g. a reset control signal line Rst and a Gate signal line disposed in a same layer), or different signal lines disposed in different layers (e.g. a data signal line and a Gate signal line disposed in different layers).

According to an embodiment of the present disclosure, orthographic projections of the metal traces disposed in different layers on the base substrate are not completely overlapped, such that each metal trace may play a role of improving diffraction of light.

According to an embodiment of the present disclosure, the metal trace is at least a part of at least one of a data signal line and a Gate signal line. Thus, impedance of the data signal line and the Gate signal line is relatively low, that is, the metal traces have relatively low impedance; moreover, data signal lines and Gate signal lines are widely distributed in the display panel, which may make the metal traces more selective. In some embodiments, a metal trace is a certain segment of the data signal line and/or the Gate signal line, but not the entire data signal line and/or the Gate signal line is all of metal traces; and in other embodiments, the entire data signal line and/or the Gate signal line is all of metal traces.

In some specific embodiments, the metal traces 30 include a first metal trace 31 and a second metal trace 32, wherein the first metal trace 31 and the second metal trace 32 belong to certain segments of different signal lines, and a schematic diagram of a distribution of the metal traces 30 may refer to FIGS. 4 and 5, FIGS. 2, 4, and 5 respectively showing three different arrangement situations of metal traces.

According to an embodiment of the present disclosure, a metal trace has a width of 1.5 to 2 microns, such as 1.5 microns, 1.6 microns, 1.7 microns, 1.8 microns, 1.9 microns, or 2.0 microns. Therefore, a metal trace with the above width may ensure a good signal transmission and ensure relatively high light transmittance of the light-transmitting display region to the greatest extent.

According to an embodiment of the present disclosure, a material of the metal traces includes at least one of aluminum, copper, titanium, silver, molybdenum, and chromium. Therefore, the above material has relatively good conductivity and a wide range of material sources, and is convenient for manufacturing metal traces in a process. Further, a material of the transparent trace includes, but is not limited to, a transparent conductive material such as ITO, IZO, or the like.

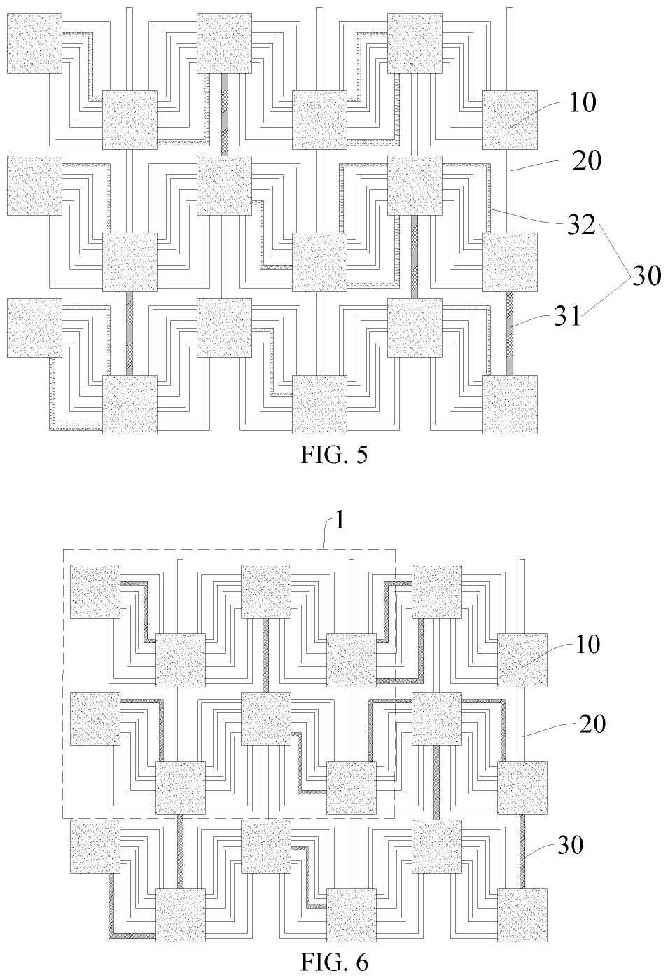

According to an embodiment of the present disclosure, multiple pixel circuits are disposed in an array, pixel circuits of (2-4) rows*(2-4) columns are defined as a pixel repeating unit 1 (as shown in FIG. 6), and pixel repeating units 1 of 2 rows*2 columns as a pixel definition region (not shown in FIG. 6), wherein at least part of signal lines in each pixel definition region are metal traces 30. Therefore, at least one metal trace is disposed within the above range, which may not only break a periodic arrangement of pixel units, effectively improve a situation of diffraction of light in the light-transmitting display region, but also ensure relatively high light transmittance in the light-transmitting display region. In a specific embodiment, as shown in FIG. 6, pixel circuits of 2 rows*4 columns are defined as a pixel repeating unit 1 (as shown in FIG. 6), and pixel repeating units 1 of 2 rows*2 columns as a pixel definition region (not shown in FIG. 6), wherein at least part of signal lines in each pixel definition region are metal traces 30.

According to an embodiment of the present disclosure, as shown in FIG. 6, at least part of signal lines in each pixel repeating unit 1 are metal traces 30. Thereby, there is at least one metal trace in the pixel circuits of (2˜4) rows*(2˜4) columns, which may better break the periodic arrangement of the pixel units, further improving a phenomenon of diffraction of light in the light-transmitting display region, and at the same time ensure the relatively high light transmittance in the light-transmitting display region.

According to an embodiment of the present disclosure, in a region of each pixel definition region, a distribution area of metal traces is less than or equal to 2% of an area occupied by the pixel definition region, for example, the distribution area of the metal traces is 2%, 1.8%, 1.6%, 1.5%, 1.4%, 1.2%, 1.0%, or 0.8% of the area occupied by the pixel definition region. Therefore, within a range of the distribution area of the metal traces, it may be ensured that the periodic arrangement of the pixel circuits is effectively broken, and the relatively high light transmittance of the light-transmitting display region may be ensured.

According to an embodiment of the present disclosure, the light transmittance of the light-transmitting display region is 11% to 15%, for example, 11%, 11.5%, 12%, 12.5%, 13%, 13.5%, 14%, 14.5%, or 15%. Therefore, the light-transmitting display region has relatively good light transmittance, and when an under-screen camera is disposed on the back of the display panel, a demand of the under-screen camera on a light input amount may be effectively met; and if the light transmittance is too high, a display quality of a display screen in the light-transmitting display region will be relatively affected, and then an overall display quality of the display panel will be affected.

According to an embodiment of the present disclosure, signal lines in the display panel at the non-light-transmitting display region meet a setting demand on signal lines in a normal display panel, that is, the signal lines in the display panel at the non-light-transmitting display region may all be metal traces, so as to ensure a good signal transmission function in the non-light-transmitting display region and a relatively good display effect.

According to an embodiment of the present disclosure, when signal lines of a display panel are manufactured, for signal lines disposed in a same layer, metal traces are manufactured in a non-light-transmitting display region by a process such as deposition, etching, etc., and transparent traces are manufactured in a light-transmitting display region again by a process such as deposition, etching, etc. When at least part of signal lines in the light-transmitting display region are metal traces, the metal traces and metal traces disposed in a same layer of the non-light-transmitting display region may be manufactured by a same process act.

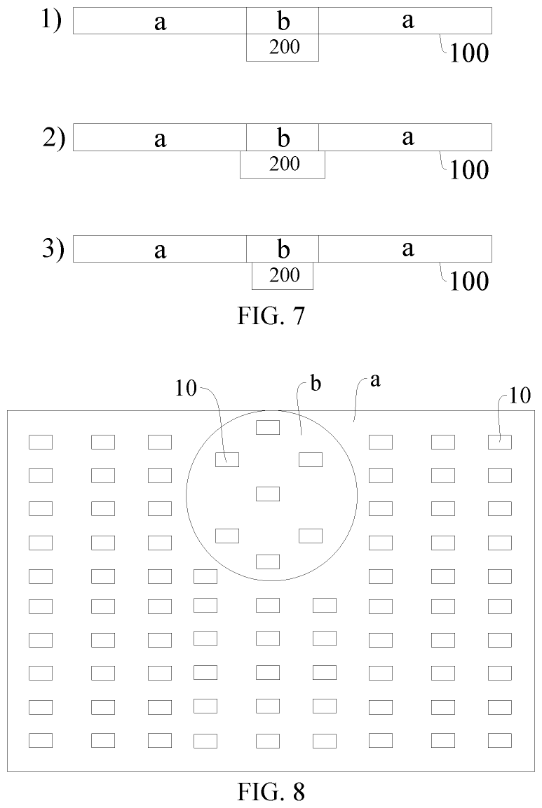

In an aspect of the present disclosure, the present disclosure provides a display device. According to an embodiment of the present disclosure, with reference to FIG. 7, the display device includes the display panel 100 described previously; and an under-screen camera 200, wherein an orthographic projection of the under-screen camera 200 on the display panel 100 has an overlapping region with the light-transmitting display region b of the display panel 100. Therefore, it is not prone to an occurrence of diffraction of light rays passing through the light-transmitting display region of the display panel, and further a shooting quality of the under-screen camera may be effectively improved. It can be understood by those skilled in the art that the display device has all features and advantages of the display panel described previously, which will not be repeated too much here.

The above “an orthographic projection of the under-screen camera 200 on the display panel 100 has an overlapping region with the light-transmitting display region b of the display panel 100” includes the following three situations: as 1) in FIG. 7, the orthographic projection of the under-screen camera 200 on the display panel 100 is overlapped with the light-transmitting display region b of the display panel 100; as 2) in FIG. 7, the orthographic projection of the under-screen camera 200 on the display panel 100 covers the light-transmitting display region b of the display panel 100; and as 3) in FIG. 7, the orthographic projection of the under-screen camera 200 on the display panel 100 is covered by the light-transmitting display region b of the display panel 100.

According to an embodiment of the present disclosure, there is no special demand on a specific category of the display device, which may be flexibly selected by those skilled in the art according to an actual situation. In some embodiments, specific categories of the display device include but are not limited to all display devices having both display and photographing functions such as a mobile phone, iPad, a notebook, and the like.

It can be understood by those skilled in the art that the display device includes a structure and a component necessary for a conventional display device in addition to the display panel and the under-screen camera described previously. Taking a mobile phone as an example, besides the display panel and the under-screen camera, the display device also includes a structure and a component such as a battery back cover, a middle bezel, a touch panel, a glass cover plate, an audio module, a motherboard, a battery, and the like.

In descriptions of this specification, descriptions of reference terms “an embodiment,” “some embodiments,” “an example,” “a specific example,” or “some examples”, etc., mean that a particular feature, a structure, a material, or a characteristic described in conjunction with the embodiment or the example is included in at least one embodiment or example of the present disclosure. In this specification, a schematic expression of the above terms does not necessarily refer to a same embodiment or example. Moreover, the specific feature, structure, material, or characteristic described may be combined in a proper mode in any one or more embodiments or examples. In addition, if there is no conflict, those skilled in the art may integrate and combine different embodiments or examples and features of different embodiments or examples described in this specification.

Although the embodiments of the present disclosure have been shown and described above, it may be understood that the above embodiments are exemplary and cannot be interpreted as limitations on the present disclosure. An ordinary person skilled in the art may make changes, modifications, substitutions, and variations to the above embodiments within the scope of the present disclosure.

1. A display panel, wherein a display region of the display panel comprises a light-transmitting display region and a non-light-transmitting display region, a pixel circuit density of the light-transmitting display region is less than a pixel circuit density of the non-light-transmitting display region, and the display panel at the light-transmitting display region comprises:
a base substrate;
a plurality of pixel circuits, disposed at a side of the base substrate; and
signal lines, wherein the signal lines are configured to connect different pixel circuits, the signal lines comprise transparent traces and metal traces, and the metal traces are arranged in an aperiodic mode.

2. The display panel of claim 1, wherein the metal traces are not completely disposed in a same layer.

3. The display panel of claim 2, wherein orthographic projections of the metal traces disposed in different layers on the base substrate are not completely overlapped.

4. The display panel of claim 1, wherein a metal trace is at least a part of at least one of a data signal line and a Gate signal line.

5. The display panel of claim 1, wherein a metal trace has a width of 1.5 microns to 2 microns.

6. The display panel of claim 1, wherein the plurality of pixel circuits are disposed in an array, defining pixel circuits of (2˜4)*(2˜4) as a pixel repeating unit, and pixel repeating units of 5 rows*5 columns as a pixel definition region, wherein at least part of the signal lines in each pixel definition region are the metal traces.

7. The display panel of claim 6, wherein at least part of the signal lines in each pixel repeat unit are the metal traces.

8. The display panel of claim 6, wherein in each pixel definition region, a distribution area of the metal traces is less than or equal to 2% of an area occupied by the pixel definition region.

9. The display panel of claim 1, wherein light transmittance of the light-transmitting display region is 11% to 15%.

10. A display device, comprising:
the display panel of claim 1; and
an under-screen camera, wherein an orthographic projection of the under-screen camera on the display panel has an overlapping region with the light-transmitting display region of the display panel.

11. The display panel of claim 7, wherein in each pixel definition region, a distribution area of the metal traces is less than or equal to 2% of an area occupied by the pixel definition region.

12. The display panel of claim 2, wherein light transmittance of the light-transmitting display region is 11% to 15%.

13. The display panel of claim 3, wherein light transmittance of the light-transmitting display region is 11% to 15%.

14. The display panel of claim 4, wherein light transmittance of the light-transmitting display region is 11% to 15%.

15. The display panel of claim 5, wherein light transmittance of the light-transmitting display region is 11% to 15%.

16. The display panel of claim 6, wherein light transmittance of the light-transmitting display region is 11% to 15%.

17. The display panel of claim 7, wherein light transmittance of the light-transmitting display region is 11% to 15%.

18. The display panel of claim 8, wherein light transmittance of the light-transmitting display region is 11% to 15%.
